(19) United States
(12) Patent Application Publication
(10) Pub. No.: US 2025/0019831 A1
(43) Pub. Date: Jan. 16, 2025

(54) WAFER TRANSFER APPARATUS, VAPOR DEPOSITION SYSTEM AND METHOD OF OPERATING THE VAPOR DEPOSITION SYSTEM

(71) Applicants: ADVANCED MICRO-FABRICATION EQUIPMENT INC. CHINA, Shanghai (CN); Nanchang Advanced Mirco-Fabrication Equipment Inc., Nanchang City, Jiangxi (CN)

(72) Inventors: Yong JIANG, Shanghai (CN); Guoyuan WANG, Shanghai (CN)

(21) Appl. No.: 18/713,148

(22) PCT Filed: Sep. 26, 2022
(86) PCT No.: PCT/CN2022/121301

§ 371 Date: May 23, 2024

(30) Foreign Application Priority Data
Dec. 27, 2021 (CN) 202111613336.1

(51) Int. Cl. C23C 16/458

(52) U.S. Cl. CPC C23C 16/4585; C23C 16/4584

(57) ABSTRACT

Disclosed are a wafer transfer apparatus, a vapor deposition system, and a method of operating the vapor deposition system. The wafer transfer apparatus includes: a susceptor on which at least one holding element is provided, each holding element including at least two substrate holders, the each of the substrate holders being correspondingly provided with two linear grooves, the two linear grooves being oppositely disposed on a periphery of the each of the substrate holders, the substrate holders being configured to accommodate wafers, the linear grooves in a same holding element being parallel disposed; a transfer mechanism including a plurality of engaging fingers, the engaging fingers being configured to lift the wafers in the same holding element simultaneously via the linear grooves and handle the wafers to preset locations. The transfer mechanism disclosed may transfer at least two wafers at a time, whereby wafer handling and transfer efficiency can be effectively enhanced, while potential wafer contamination can be mitigated.

### FIELD

The disclosure relates to semiconductor manufacturing, and more particularly relates to a wafer transfer apparatus, a vapor deposition system, and a method of operating the vapor deposition system.

### BACKGROUND

A wafer deposition process generally involves: first placing wafers on a susceptor, and then loading the entire susceptor into a vapor deposition equipment where the wafers are subjected to the deposition process; upon completion of the deposition process, unloading the entire susceptor from the vapor deposition equipment and then retrieving the wafers from the susceptor for storage. In the wafer deposition process, the operations of loading the wafers on the susceptor and retrieving the wafers from the susceptor are conventionally performed manually or by a wafer transfer mechanism. However, manual handling of the wafers is not only inefficient, but also likely increase particle deposition on the wafers, deteriorating quality of the wafers; as to an existing wafer transfer mechanism, although it can mitigate wafer contamination to some extent, its working capacity only allows for handling one piece of wafer at a time, such that it is still inefficient in wafer handling and transfer. Therefore, a need arises to modify or improve conventional wafer handling and transfer mechanisms.

### SUMMARY

An object of the disclosure is to provide a wafer transfer apparatus, a vapor deposition system, and a method of using the vapor deposition system, where a transfer mechanism can transfer at least two wafers at a time, effectively enhancing wafer handling and transfer efficiency and reducing potential wafer contamination from particles.

To achieve the above and other objects, embodiments of the disclosure provide a technical solution infra:

a wafer transfer apparatus, comprising:
a susceptor on which at least one holding element is provided, each holding element comprising at least two substrate holders, each of the substrate holders being correspondingly provided with two linear grooves, the two linear grooves being oppositely disposed on a periphery of the each of the substrate holders, the substrate holders being configured to accommodate wafers, the linear grooves in a same holding element being parallel disposed;
a transfer mechanism comprising a plurality of engaging fingers, the engaging fingers being configured to lift the wafers in the same holding element simultaneously via the linear grooves and transfer the wafers to preset locations.

In some example implementations, within the same holding element, a linear groove disposed between at least two neighboring substrate holders is a common groove.

In some example implementations, the common groove has a width greater than that of rest linear grooves.

In some example implementation, within the same holding element, only one linear groove is disposed between neighboring substrate holders, the only one linear groove serving as the common groove, and the number of the linear grooves is greater than that of the substrate holders by one.

In some example implementations, the holding element further comprises carrying rings, each of the carrying rings being disposed on the corresponding substrate holder, each carrying ring having an outer edge extending into the corresponding linear groove and an inner edge configured to hold a wafer.

In some example implementations, the engaging fingers comprise a single-sided engaging finger and at least one doubled-sided engaging finger, the double-sided engaging finger being inserted into the common groove to lift outer edges of neighboring carrying rings, the single-sided engaging finger being inserted into a linear groove other than the common groove within the same holding element to lift an outer edge of the corresponding carrying rings.

In some example implementations, each double-sided engaging finger has a width greater than that of respective single-sided engaging fingers.

In some example implementations, at least one dented portion is provided on each of the engaging fingers, each dented portion being configured to secure the outer edge of the corresponding carrying ring.

In some example implementations, each dented portion is arc-shaped; and two dented portions are provided on each double-sided engaging finger, and one dented portion is provided on the respective single-sided engaging fingers.

In some example implementations, the substrate holders are arranged along a periphery of the susceptor, respective centers of all substrate holders being equidistant from the center of the susceptor.

Embodiments of the disclosure further provide a vapor deposition system, comprising: a reaction chamber, a transfer chamber connected to the reaction chamber, a separation and storage chamber connected to the transfer chamber, and the wafer transfer apparatus as described supra;
the wafer transfer apparatus comprises a first susceptor and a second susceptor, the first susceptor being disposed in the reaction chamber, the second susceptor being disposed in the separation and storage chamber, a transfer mechanism being disposed in the transfer chamber.

In some example implementations, a first susceptor supporting mechanism configured to hold the first susceptor is provided in the reaction chamber, the first susceptor supporting mechanism being operable to bring the first susceptor to rotate.

In some example implementations, the separation and storage chamber comprises:
a cassette configured to store wafers;
a second susceptor supporting mechanism configured to hold the second susceptor, the second susceptor supporting mechanism being operable to bring the second susceptor to rotate;
a plurality of lift pin kits disposed on the second susceptor supporting mechanism, each of the lift pin kits penetrating the corresponding substrate holder on the second susceptor so as to lift a wafer on the corresponding substrate holder;
a robot configured to transfer wafers between the second susceptor and the cassette.

In some example implementations, each of the lift pin kits is operable to perform an up and down motion along an axial direction of the second susceptor supporting mechanism.

Embodiments of the disclosure still provide a method of operating the vapor deposition system described supra, comprising: a loading operation and an unloading operation;
the loading operation comprises:
engaging fingers of a transfer mechanism accessing a separation and storage chamber to lift to-be-processed wafers accommodated in corresponding at least one holding element via linear grooves in a second susceptor;
the engaging fingers accessing a reaction chamber to place, from top to down, the to-be-processed wafers on the at least one holding element of a first susceptor;
the unloading operation comprises:
the engaging fingers accessing the reaction chamber to lift as-deposited wafers accommodated in the corresponding at least one holding element via linear grooves in a first susceptor;
the engaging fingers accessing the separation and storage chamber to place, from top to down, the as-deposited wafers on the at least one holding element of the second susceptor.

In some example implementations, the loading operation further comprises:
each lift pin kit in the separation and storage chamber being lifted;
a robot in the separation and storage chamber lifting the to-be-processed wafers from within the cassette and placing the to-be-processed wafers onto the corresponding lift pin kits;
each of the lift pin kits moving down so as to place the to-be-processed wafers on the corresponding at least one holding element of the second susceptor.

In some example implementations, the unloading operation further comprises:
each of the lift pin kits in the separation and storage chamber being lifted to lift the as-deposited wafers accommodated in the corresponding at least one holding element of the second susceptor;
the robot in the separation and storage chamber lifting the as-deposited wafers lifted by the lift pin kits and placing the as-deposited wafers into the cassette.

In some example implementations, the first susceptor supporting mechanism in the reaction chamber brings the first susceptor to rotate such that each holding element of the first susceptor sequentially stops at first preset locations to cooperate with the engaging fingers to place the to-be-processed wafers or retrieve the as-deposited wafers;
the second susceptor supporting mechanism in the separation and storage chamber brings the second susceptor to rotate such that each holding element of the second susceptor sequentially stops at second preset locations to cooperate with the engaging fingers to place the as-deposited wafers or retrieve the to-be-processed wafers.

The disclosure offers the benefits below:
The disclosure provides a wafer transfer apparatus, a vapor deposition system, and a method of operating the vapor deposition system, where each holding element of the susceptor comprises at least two substrate holders for accommodating wafers and two linear grooves oppositely disposed on the periphery of each substrate holder, and the engaging fingers of the transfer mechanism may simultaneously lift the wafers accommodated in the same holding element to transfer them to preset locations; in this way, the transfer mechanism can transfer at least two wafers at a time, whereby wafer handling and transfer efficiency can be effectively enhanced and potential wafer contamination from particles can be reduced.

In the disclosure, the carrying rings disposed on the substrate holders have outer edges extending into the corresponding linear grooves and inner edges for holding wafers, respectively; in this way, to transfer the wafers, the engaging fingers of the transfer mechanism may lift the wafers carried by the inner edges of the carrying rings via the outer edges of the carrying rings, such that the engaging fingers do not contact the wafers, preventing the wafers from being contaminated from particles during the transfer process, further ensuring cleanness of the wafers.

In the disclosure, at least one arc-shaped dented portion is further provided on the engaging fingers; the dented portions can secure the outer edges of the carrying rings such that the transfer mechanism can stably lift the carrying rings, further ensuring safe transfer of the wafers.

In the disclosure, the lift pin kits may perform a lifting motion along an axial direction of the second susceptor supporting mechanism; when the lift pin kits are lifted, the robot may lift the wafers from their backsides to place from top to down the wafers onto the corresponding lift pin kits, or lift, from down to top, the lifted wafers from their backsides and place the wafers into the cassette, which can thus prevent the front sides of the wafers from being contaminated from particles.

### BRIEF DESCRIPTION OF THE DRAWINGS

FIG. 1 is a structural schematic diagram of a susceptor in a wafer transfer apparatus according to some example embodiments of the disclosure;

FIG. 2 is a structural schematic diagram of a transfer mechanism in the wafer transfer apparatus according to some example embodiments of the disclosure;

FIG. 3 is a structural schematic diagram of engaging fingers in the wafer transfer apparatus according to some example embodiments of the disclosure;

FIG. 4 is schematic sectional view of the susceptor in the wafer transfer apparatus according to some example embodiments of the disclosure;

FIG. 5 is a schematic diagram illustrating that wafers in a reaction chamber of a vapor deposition system are lifted by the engaging fingers according to some example embodiments of the disclosure;

FIG. 6 is a schematic diagram illustrating that wafers in a separation and storage chamber of the vapor deposition system are placed by the engaging fingers according to some embodiments of the disclosure.

### DETAILED DESCRIPTION

Hereinafter, the disclosure will be described in further detail through example embodiments with reference to the accompanying drawings. The benefits and features of the disclosure will become more apparent to those skilled in the art after having read the description below and the appended claims. It is noted that the drawings are only schematic with imprecise proportions, which are only used to facilitate illustration of the objects of the embodiments of the disclosure in a convenient and clear manner.

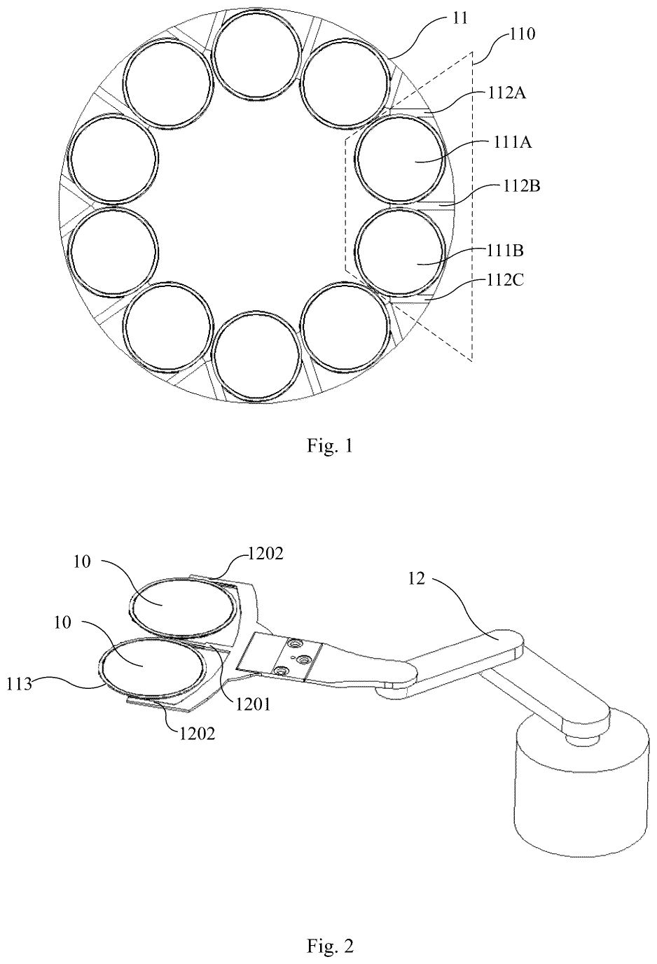

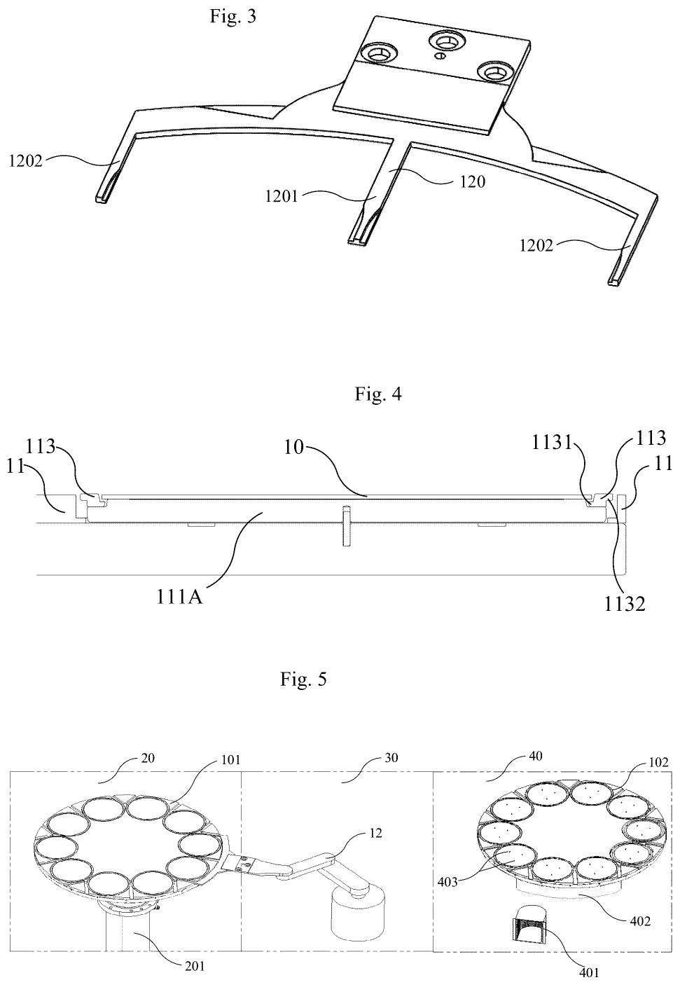

As illustrated in FIGS. 1 to 4, an example wafer transfer apparatus comprises: a susceptor 11 on which at least one holding element 110 is provided, each holding element 110 comprising at least two substrate holders, each of the substrate holders being correspondingly provided with two linear grooves, the two linear grooves being oppositely disposed on a periphery of each of the substrate holders, the substrate holders being configured to accommodate wafers 10, the linear grooves in the same holding element 110 being disposed in parallel; a transfer mechanism 12 comprising a plurality of engaging fingers (1201, and 1202 illustrated in FIG. 2 and in FIG. 3), the engaging fingers being configured to lift the wafers 10 in the same holding element 110 simultaneously via the linear grooves and transfer the wafers 10 to preset locations.

Further referring to FIG. 1, the substrate holders are arranged along the periphery of the susceptor 11, respective centers of all substrate holders being equidistant from the center of the susceptor 11.

It is understood that, in some alternative example embodiments, within the same holding element 110, only one linear groove is disposed between neighboring substrate holders, the only one linear groove serving as a common groove such that the number of the linear grooves is greater than that of the substrate holders by one.

Specifically, in this example embodiment, five holding elements 110 can be provided on the susceptor 11, all of which are arranged at intervals along the circumference of the susceptor 11. Within the same holding element 110, two substrate holders, which are respectively denoted as first substrate holder 111A and second substrate holder 111B, and three linear grooves, which are respectively denoted as first linear groove 112A, second linear groove 112B, and third linear groove 112C, may be provided, where the first linear groove 112A and the second linear groove 112B are oppositely disposed on the periphery of the first substrate holder 111A, and the second linear groove 112B and the third linear groove 112C are oppositely disposed on the periphery of the second substrate holder 111B; in this case, only one second linear groove 112B is disposed between the first substrate holder 111A and the second substrate holder 111B, the second linear groove 112B thusly serving as the common groove. More specifically, at least one (112A, 112B, or 112C) of the linear grooves disposed on the periphery of each of the substrate holders in the same holding element 110 can be disposed along the radial direction of the susceptor 11; in addition, the first linear groove 112A, the second linear groove 112B, and the third linear groove 112C are further engaged with the periphery of the susceptor 11 such that the engaging fingers of the transfer mechanism 12 may be inserted into the first linear groove 112A, the second linear groove 112B, and the third linear groove 112C, respectively, to lift the wafers 10 on the same holding element 110, whereby wafer transfer is implemented. In some example implementations, the second linear groove 112B is disposed along the radial direction of the susceptor 11, but the disclosure is not limited thereto.

Specifically, in the present example embodiment, since the second linear groove 112B serving as the common groove is disposed on the peripheries of both first substrate holder 111A and second substrate holder 111B, the width of the second linear groove 112B is greater than that of the first linear groove 112A and that of the third linear groove 112C in the same holding element 110. In addition, within the same holding element 110, the number of the common grooves may be less than that of the substrate holders by one; however, the disclosure is not limited thereto.

In a further example embodiment, within the same holding element 110, a linear groove disposed between at least two neighboring substrate holders is a common groove. In an example implementation, a width of the common groove is greater than that of the rest linear groove(s).

Specifically, in a case that three or more substrate holders are provided in the same holding element 110, the common groove is alternatively provided only between one pair (i.e., two neighboring) of the substrate holders, while no common groove is provided between the rest neighboring substrate holders; another alternative is that the common groove is provided only between two neighboring pairs of the substrate holders, while no common groove is provided between the rest neighboring substrate holders; however, the disclosure is not limited thereto.

Referring to FIG. 1, FIG. 2, and FIG. 4 together, the holding element 110 further comprises carrying rings 113, each of the carrying rings 113 being disposed on the corresponding substrate holder, each of the carrying rings 113 having an outer edge extending into the corresponding linear groove and an inner edge configured to hold the corresponding wafer 10.

Specifically, in the present example embodiment, within the same holding element 110, the number of the carrying rings 113 is equal to that of the substrate holders, i.e., two; and the diameter of the inner edge of each of the carrying rings 113 is smaller than that of the corresponding wafer 10, such that the inner edge of each of the carrying rings 113 may hold one wafer 10. More specifically, within the same holding element 110, in the case that the two carrying rings 113 are disposed on the first substrate holder 111A and the second substrate holder 111B, respectively, the inner edges of the two carrying rings 113 may correspondingly abut against respective top surfaces of the first substrate holder 111A and the second substrate holder 111B, while the outer edges of the two carrying rings 113 are distant from the corresponding first substrate holder 111A and second substrate holder 11B, and the outer edges of the two carrying rings 113 extend towards the second linear groove 112B which serves as the common groove. In some example implementations, the height difference between the inner edge and the outer edge of each of the carrying rings 113 is not less than the thickness of the wafer 10, such that the carrying rings 113 may securely hold the wafers 10; however, the disclosure is not limited thereto.

Please refer to FIG. 1, FIG. 2, and FIG. 3 together, the engaging fingers 120 further comprise a single-sided engaging finger 1202 and at least one double-sided engaging finger 1201, the double-sided engaging finger 1201 being inserted into the common groove to lift the outer edges of neighboring carrying rings 113, the single-sided engaging finger 1202 being inserted into a corresponding linear groove other than the common groove within the same holding element 110 to lift the outer edge of the corresponding carrying ring 113.

In some example embodiments, the width of the double-sided engaging finger 1201 is greater than that of the single-sided engaging finger 1202.

Specifically, in this example embodiment, the number of the engaging fingers 120 in the transfer mechanism 12 is equal to that of the linear grooves in each of the holding elements 110, i.e., three; the number of the two-sided engaging finger 1201 among the engaging fingers 120 is equal to that of the common groove in the same holding element 110, i.e., one; and the number of the single-sided engaging fingers 1202 is equal to that of the linear grooves other than the common groove in the same holding element 110, i.e., two. Since all of the linear grooves (112A, 112B, and 112C) in the same holding element 110 are arranged parallel to each other, the single-sided engaging fingers 1202 are all arranged parallel to the double-sided engaging finger 1201, such that the two single-sided engaging fingers 1202 may be inserted into the first linear groove 112A and the third linear groove 112C of the same holding element 110, respectively, and the double-sided engaging finger 1201 may be inserted into the second linear groove 112B; in this way, respective outer edges of all carrying rings 113 in the same holding element 110 are lifted, and the wafers 10 resting on the inner edges of the carrying rings 113 are thus lifted and transferred to preset locations. However, the disclosure is not limited thereto.

In this example embodiment, when the transfer mechanism 12 transfers the wafers 10, the single-sided engaging finger 1202 and the double-sided engaging finger 1201 in the transfer mechanism 12 only contact respective outer edges of the carrying ring 113, without contacting the wafers 10; this may effectively avoid the wafers 10 from being contaminated from particles; meanwhile, since at least two wafers 10 are accommodated in the same holding element 110, the transfer mechanism 12 may handle at least two wafers 10 at a time, whereby wafer transfer efficiency can be effectively enhanced.

Please continue reference to FIG. 2 and FIG. 3, at least one dented portion is provided on respective engaging fingers 120, each dented portion being configured to secure the outer edge of the corresponding carrying ring 113.

It is understood that in some other example embodiments, each dented portion is arc-shaped, where the double-sided engaging finger 1201 is provided with two dented portions, and the single-sided engaging fingers 1202 is provided with one dented portion.

Specifically, in this example embodiment, the arc opening of each dented portion on the double-sided engaging finger 1201 faces the single-sided engaging finger 1202, while the arc opening of the dented portion of the single-sided engaging finger 1202 faces the double-sided engaging finger 1201, i.e., each dental portion on the double-sided engaging finger 1201 is disposed opposite the dented portion on the proximal single-sided engaging finger 1202; the dented portion on the single-sided engaging finger 1202 and the oppositely disposed dented portion on the double-sided engaging finger 1201 are configured to secure the outer edge of the same carrying ring 113, respectively, such that the transfer mechanism 12 can stably lift the carrying ring 113 and the wafer 10. In addition, the two dented portions on the double-sided engaging finger 1201 may be symmetrically provided, such that the double-sided engaging finger 1201 is uniformly stressed when lifting neighboring carrying rings 113 simultaneously, thereby lifting the carrying rings 113 more stably. In some example implementations, the radian of each of the dented portions may be identical to that of the outer edge of the carrying ring 113, such that the outer edge of the carrying ring 113 can be exactly inserted into the corresponding dented portion; in this way, the dented portion can hold the outer edge of the carrying ring 113 more stably; however, the disclosure is not limited thereto.

Referring to FIGS. 5˜6, embodiments of the disclosure further provide a vapor deposition system, comprising: a reaction chamber 20, a transfer chamber 30 connected to the reaction chamber 20, a separation and storage chamber 40 connected to the transfer chamber 30, and the wafer transfer apparatus described supra; where the wafer transfer apparatus is provided with two susceptors, i.e., a first susceptor 101 and a second susceptor 102, the first susceptor 101 being disposed in the reaction chamber 20, the second susceptor 102 being disposed in the separation and storage chamber 40; and the transfer mechanism 12 is disposed in the transfer chamber 30, where engaging fingers 120 of the transfer mechanism 20 may access the reaction chamber 20 and the separation and storage chamber 40.

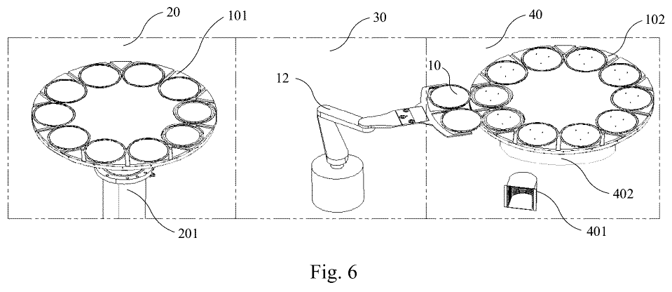

Continuing reference to FIG. 5 and FIG. 6, a first susceptor supporting mechanism 201 configured to hold the first susceptor 101 is provided in the reaction chamber 20, the first susceptor supporting mechanism 201 being operable to bring the first susceptor 101 to rotate.

Specifically, in this example embodiment, the reaction chamber 20 refers to a chamber in which the wafers 10 are subjected to a deposition process. The wafers 10 may be loaded in the first susceptor 101 via the transfer mechanism 12, and a heater disposed on the first susceptor supporting mechanism 201 may heat the first susceptor 101 such that the wafers 10 accommodated in the first susceptor 101 are uniformly heated; in this way, deposition processing can be carried out. More specifically, the first susceptor supporting mechanism 201 may be driven to rotate by a first magnetohydrodynamic fluid (i.e., a first motor), further bringing the first susceptor 101 and the wafers 10 accommodated in the first susceptor 101 to rotate. The first magnetohydrodynamic fluid may be disposed in the reaction chamber 20, and optionally, the first magnetohydrodynamic fluid may be disposed outside the reaction chamber 20; the disclosure is not limited thereto.

Continuing reference to FIG. 5 and FIG. 6, the separation and storage chamber 40 comprises: a cassette 401 configured to store wafers 10; a second susceptor supporting mechanism 402 configured to hold the second susceptor 102, the second susceptor supporting mechanism 402 being operable to bring the second susceptor 102 to rotate; a plurality of lift pin kits 403 disposed on the second susceptor supporting mechanism 402, each of the lift pin kits 403 correspondingly penetrating substrate holders of the second susceptor so as to lift the wafers 10; and a robot configured to transfer the wafers 10 between the second susceptor 102 and the cassette 401.

It is understood that in some other example embodiments, each of the lift pin kits 403 is operable to perform a lifting motion along the axial direction of the second susceptor supporting mechanism 402.

Specifically, in this example embodiment, the second susceptor supporting mechanism 402 may be driven to rotate by a second magnetohydrodynamic fluid (i.e., a second motor), further bringing the second susceptor 102 and the wafers 10 accommodated on the second susceptor 102 to rotate; the second magnetohydrodynamic fluid may be disposed in the separation and storage chamber 40, but the disclosure is not limited thereto.

Specifically, in this example embodiment, each of the lift pin kits 403 may comprise a plurality of lift pins, each lift pin correspondingly penetrating a substrate holder on the second susceptor 102; the lifting motion of each of the lift pin kits 403 may be controlled by a pneumatic cylinder, whereby lifting of the wafers 10 is controlled. More specifically, to transfer the wafers 10 from the cassette 401 to the second susceptor 102, in which case no wafers 10 are accommodated in the second susceptor 102, one alternative is that each of the lift pin kits 403 is first lifted to facilitate the robot to place, from top to down, the wafers 10 onto corresponding lift pin kits 403, and then each of the lift pin kits 403 moves down such that the wafers 10 land onto respective carrying rings and substrate holders of the second susceptor 102. To transfer the wafers 10 from the second susceptor 102 into the cassette 401, in which case wafers 10 are already present in the second susceptor 102, a likewise alternative is that each of the lift pin kits 403 is first lifted such that the wafers 10 are separated from the carrying rings and substrate holders of the second susceptor 102, which facilitates the robot to lift, from down to top, the wafers 10 lifted by the corresponding lift pin kits 403 and load the wafers 10 into the cassette 401. In some example implementations, when the robot handles the wafers 10 between the second susceptor 102 and the cassette 401, the transfer may be done by lifting the wafers from their backsides or by applying a suction cup to hold respective backsides of the wafers 10, thereby preventing the front sides of the wafers 10 from being contaminated from particles; however, the disclosure is not limited thereto.

In another aspect, embodiments of the disclosure still provide a method of operating the vapor deposition system described supra, comprising: a loading operation and an unloading operation, where the loading operation comprises: step S1. the engaging fingers 120 of the transfer mechanism 12 accessing the separation and storage chamber 40 so as to lift the to-be-processed wafers accommodated on corresponding at least one holding element 110 via linear grooves in the second susceptor 102; step S2. the engaging fingers 120 accessing the reaction chamber 20 to place, from top to down, the to-be-processed wafers on the at least one holding element 110 of a first susceptor 101; and the unloading operation comprises: step S3. the engaging fingers 120 accessing the reaction chamber 20 so as to lift as-deposited wafers on the corresponding at least one holding element 110 via the linear grooves in the first susceptor 101; step S4. the engaging fingers 120 accessing the separation and storage chamber 40 so as to place, from top to down, the as-deposited wafers on the at least one holding element 110 of the second susceptor 102.

It will be appreciated that, in some other example embodiments, the loading operation further comprises before performing step S1: each lift pin kit 403 in the separation and storage chamber 40 being lifted; the robot in the separation and storage chamber 40 lifting the to-be-processed wafers from within the cassette 401 and place them onto the corresponding lift pin kits 403; each of the lift pin kits 403 moving down so as to place the to-be-processed wafers on the corresponding at least one holding element 110 of the second susceptor 102.

In some example embodiments, the unloading operation further comprises after performing step S4: each of the lift pin kits 403 in the separation and storage chamber 40 being lifted to lift the as-deposited wafers accommodated in the corresponding at least one holding element 110 of the second susceptor 102; the robot in the separation and storage chamber 40 lifting the as-deposited wafers lifted by the lift pin kits 403 and placing them into the cassette 401.

In some example embodiments, the first susceptor supporting mechanism 201 in the reaction chamber 20 brings the first susceptor 101 to rotate such that each holding element 110 of the first susceptor 101 sequentially stops at first preset locations so as to cooperate with the engaging fingers 120 to place the to-be-processed wafers or retrieve the as-deposited wafers; the second susceptor supporting mechanism 402 in the separation and storage chamber 40 brings the second susceptor 102 to rotate such that each holding element 110 of the second susceptor 102 sequentially stops at second preset locations so as to cooperate with the engaging fingers 120 to place the as-deposited wafers or retrieve the to-be-processed wafers.

Specifically, in this example embodiment, to carry out the loading operation or the unloading operation, the first magnetohydrodynamic fluid may be intermittently activated via parameter setting, and upon each activation, the first magnetohydrodynamic fluid may drive the first susceptor supporting mechanism 201 to rotate by a first preset angle, thereby bringing the first susceptor 101 also to rotate by the first preset angle, such that each of the holding elements 110 of the first susceptor 101 may sequentially stop at first preset locations; in this way, the engaging fingers 120 may carry out the transfer operations for all wafers at the first preset locations, whereby wafer transfer efficiency can be effectively enhanced. In some example implementations, the first preset angle may be determined based on the number of the holding elements 110 of the first susceptor 101. For example, in the case that the first susceptor 101 is provided with four holding elements 110, the first preset angle may be 90°; in the case that the first susceptor 101 is provided with five holding elements 110, the first preset angle may be 72°; however, the disclosure is not limited thereto.

Likewise, the second magnetohydrodynamic fluid may be activated via parameter setting, and upon each activation, the second magnetohydrodynamic fluid may drive the second susceptor supporting mechanism 402 to rotate by a second preset angle, thereby bringing the second susceptor 102 also to rotate by the second preset angle, such that each of the holding elements 110 of the second susceptor 102 may sequentially stop at second preset locations; in this way, the robot may carry out transfer operations for all wafers at the second preset locations, whereby wafer transfer efficiency can be effectively enhanced. In some example implementations, the second preset angle may be determined based on the number of the holding elements 110 of the second susceptor 102, but the disclosure is not limited thereto.

As described supra, embodiments of the disclosure provide a wafer transfer apparatus, a vapor deposition system, and a method of operating the vapor deposition system; by providing at least one holding element on the susceptor, each holding element comprising at least two substrate holders configured to hold wafers, the each of the substrate holders being correspondingly provided with two linear grooves, and by providing a plurality of engaging fingers on a transfer mechanism, the engaging fingers being configured to simultaneously lift the wafers in the same holding element via the linear grooves and transfer the wafers to preset locations, the transfer mechanism is enabled to transfer at least two wafers at a time, which can effectively enhance wafer handling and transfer efficiency and effectively reduce potential wafer contamination from particles. In the embodiments of the disclosure, each carrying ring has an outer edge extending into a corresponding linear groove and an inner ring for holding a wafer, such that to transfer the wafers, the engaging fingers of the transfer mechanism may lift the wafers on respective inner edges of the carrying rings via the outer edges of the carrying rings; as such, the engaging fingers do not contact the wafers, which can avoid the wafers from being contaminated from particles during the transfer process, further ensuring cleanness of the wafers. At least one arc-shaped dented portion for securing the carrying ring is further provided on respective engaging fingers, enabling the transfer mechanism to stably lift the carrying rings, further ensuring safety of wafer transfer.

Although the disclosure has been described in detail via the example embodiments, it is understood that the description supra does not amount to limitations to the disclosure. After having read the disclosure, various modifications and substitutions will be obvious to those skilled in the art. Therefore, the extent of protection of the disclosure should be limited by the appending claims.

1. A wafer transfer apparatus, comprising:
a susceptor on which at least one holding element is provided, each holding element comprising at least two substrate holders, each of the substrate holders being correspondingly provided with two linear grooves, the linear grooves being oppositely disposed on a periphery of the each of the substrate holders, the substrate holders being configured to accommodate wafers, the linear grooves in a same holding element being parallel disposed;
a transfer mechanism comprising a plurality of engaging fingers, the engaging fingers being configured to lift the wafers on the same holding element simultaneously via the linear grooves and transfer the wafers to preset locations.

2. The wafer transfer apparatus of claim 1, wherein within the same holding element, a linear groove disposed between at least two neighboring substrate holders is a common groove.

3. The wafer transfer apparatus of claim 2, wherein the common groove has a width greater than that of rest linear grooves.

4. The wafer transfer apparatus of claim 1, wherein within the same holding element, only one linear groove is disposed between neighboring substrate holders, the only one linear groove serving as the common groove, and the number of the linear grooves is greater than that of the substrate holders by one.

5. The wafer transfer apparatus of claim 4, wherein the holding element further comprises carrying rings, each of the carrying rings being disposed on the corresponding substrate holder, each carrying ring having an outer edge extending into the corresponding linear groove and an inner edge configured to hold a wafer.

6. The wafer transfer apparatus of claim 5, wherein the engaging fingers comprise a single-sided engaging finger and at least one doubled-sided engaging finger, the double-sided engaging finger being inserted into the common groove to lift outer edges of neighboring carrying rings, the single-sided engaging finger being inserted into a linear groove other than the common groove within the same holding element to lift an outer edge of the corresponding carrying rings.

7. The wafer transfer apparatus of claim 6, wherein each double-sided engaging finger has a width greater than that of respective single-sided engaging fingers.

8. The wafer transfer apparatus of claim 7, wherein at least one dented portion is provided on each of the engaging fingers, each dented portion being configured to secure the outer edge of the corresponding carrying ring.

9. The wafer transfer apparatus of claim 8, wherein each dented portion is arc-shaped; and wherein two dented portions are provided on each double-sided engaging finger, and one dented portion is provided on the respective single-sided engaging fingers.

10. The wafer transfer apparatus of claim 1, wherein the substrate holders are arranged along a periphery of the susceptor, respective centers of all substrate holders being equidistant from the center of the susceptor.

11. A vapor deposition system, comprising: a reaction chamber, a transfer chamber connected to the reaction chamber, a separation and storage chamber connected to the transfer chamber, and the wafer transfer apparatus of claim 1;
wherein the wafer transfer apparatus comprises a first susceptor and a second susceptor, the first susceptor being disposed in the reaction chamber, the second susceptor being disposed in the separation and storage chamber, a transfer mechanism being disposed in the transfer chamber.

12. The vapor deposition system of claim 11, wherein a first susceptor supporting mechanism configured to hold the first susceptor is provided in the reaction chamber, the first susceptor supporting mechanism being operable to bring the first susceptor to rotate.

13. The vapor deposition system of claim 12, wherein the separation and storage chamber comprises:
a cassette configured to store wafers;
a second susceptor supporting mechanism configured to hold the second susceptor, the second susceptor supporting mechanism being operable to bring the second susceptor to rotate;
a plurality of lift pin kits disposed on the second susceptor supporting mechanism, each of the lift pin kits penetrating the corresponding substrate holder of the second susceptor so as to lift a wafer on the corresponding substrate holder;
a robot configured to transfer wafers between the second susceptor and the cassette.

14. The vapor deposition system of claim 13, wherein each of the lift pin kits is operable to perform a lifting motion along an axial direction of the second susceptor supporting mechanism.

15. A method of operating the vapor deposition system of claim 11, comprising: a loading operation and an unloading operation;
wherein the loading operation comprises:
engaging fingers of a transfer mechanism accessing a separation and storage chamber to lift to-be-processed wafers accommodated in corresponding at least one holding element via linear grooves on a second susceptor;
the engaging fingers accessing a reaction chamber to place, from top to down, the to-be-processed wafers on the at least one holding element of a first susceptor;
wherein the unloading operation comprises:
the engaging fingers accessing the reaction chamber to lift as-deposited wafers accommodated in the corresponding at least one holding element via linear grooves on a first susceptor;
the engaging fingers accessing the separation and storage chamber to place, from top to down, the as-deposited wafers on the at least one holding element of the second susceptor.

16. The method of operating the vapor deposition system according to claim 15, wherein the loading operation further comprises:
each lift pin kit in the separation and storage chamber being lifted;
a robot in the separation and storage chamber lifting the to-be-processed wafers from within the cassette and place the to-be-processed wafers onto the corresponding lift pin kits;
each of the lift pin kits moving down so as to place the to-be-processed wafers on the corresponding at least one holding element of the second susceptor.

17. The method of operating the vapor deposition system according to claim 15, wherein the unloading operation further comprises:
each of the lift pin kits in the separation and storage chamber being lifted to lift the as-deposited wafers accommodated in the corresponding at least one holding elements of the second susceptor;
the robot in the separation and storage chamber lifting the as-deposited wafers lifted by the lift pin kits and placing the as-deposited wafers into the cassette.

18. The method of operating the vapor deposition system according to claim 15, wherein the first susceptor supporting mechanism in the reaction chamber brings the first susceptor to rotate such that each holding element of the first susceptor sequentially stops at first preset locations to cooperate with the engaging fingers to place the to-be-processed wafers or retrieve the as-deposited wafers;
the second susceptor supporting mechanism in the separation and storage chamber brings the second susceptor to rotate such that each holding element of the second susceptor sequentially stops at second preset locations to cooperate with the engaging fingers to place the as-deposited wafers or retrieve the to-be-processed wafers.
